(19) United States
(12) Patent Application Publication
(10) Pub. No.: US 2024/0223009 A1
(43) Pub. Date: Jul. 4, 2024

(54) SYSTEMS AND METHODS FOR COOLING A WIRELESS CHARGING SYSTEM

(71) Applicant: iOttie Inc., Northvale, NJ (US)

(72) Inventors: Jeremy Leeds-Frank, Mineola, NY (US); Inhwan Cho, Leonia, NJ (US)

(73) Assignee: iOttie Inc., Northvale, NJ (US)

(21) Appl. No.: 18/535,685

(22) Filed: Dec. 11, 2023

Related U.S. Application Data
(60) Provisional application No. 63/478,305, filed on Jan. 3, 2023.

(51) Int. Cl. H02J 50/00; H02J 50/10; H05K 7/20

(52) U.S. Cl. CPC H02J 50/005; H02J 50/10; H05K 7/20154; H05K 7/20436; H05K 7/205

(57) ABSTRACT

Disclosed herein is a wireless charging system for charging a battery of an electronic device. In an exemplary aspect, the wireless charging system includes a charging unit provided with an inductive coil, for generating an electromagnetic field such that when the electronic device is placed near the charging unit, a current is induced in the inductive coil charging the battery of the electronic device; a thermoelectric module thermally coupled to the charging unit and configured to cool the charging unit; a first thermally conductive sheet disposed between and in contact with the charging unit and the thermoelectric module; a heat sink dissipating heat generated from the charging unit; a fan generating airflow in order to transfer the heat dissipated from the heat sink; and a second thermally conductive sheet disposed between and in contact with the heat sink and the thermoelectric module.

### CROSS-REFERENCE TO RELATED APPLICATIONS

This application claims benefit of priority to the U.S. Provisional Application No. 63/478,305, filed Jan. 3, 2023, which is herein incorporated by reference.

### TECHNICAL FIELD

Aspects of the present disclosure relate generally to wireless charging systems, and more particularly, to cooling a wireless charging system.

### BACKGROUND

Although wireless charging is a useful feature in electronic devices such as smartphones, it generates thermal energy that affects the electrons in the electronic devices. This can lead to poor charging performance and dangerous effects such as battery damage.

One approach to preventing heat damage involves discontinuing the charging process when a threshold temperature or threshold current intensity is reached in a given charging session. However, this approach increases the time to charge an electronic device. Approaches that involve using open air to indirectly cool electronic devices fail to efficiently cool the devices in high power charges (e.g., “fast charging mode”). Approaches that involve spraying cold air onto electronic devices are effective at cooling, but in order to reduce the flow loss of the air ejected in the cooling fan, the air has to be formed into the shape in which the forming location and shape of the vent are similar to the shape of the cooling fan. Because the shape and position of the cooling fan greatly affect heat reduction, this direct cooling method is also inefficient because it is influenced by attributes that may not be constant (e.g., the air shape may change and the fan may get shifted unknowingly).

Conventional wireless charging systems are unable to address these issues. Accordingly, there exists a need for improvements in such wireless charging systems.

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

In an exemplary aspect, the techniques described herein relate to a wireless charging system for charging a battery of an electronic device including: a charging unit provided with an inductive coil, for generating an electromagnetic field such that when the electronic device is placed near the charging unit, a current is induced in the inductive coil charging the battery of the electronic device; a thermoelectric module thermally coupled to the charging unit and configured to cool the charging unit; a first thermally conductive sheet disposed between and in contact with the charging unit and the thermoelectric module; a heat sink dissipating heat generated from the charging unit; a fan generating airflow in order to transfer the heat dissipated from the heat sink; and a second thermally conductive sheet disposed between and in contact with the heat sink and the thermoelectric module.

In some aspects, the techniques described herein relate to a wireless charging system, further including at least one other fan generating airflow in order to transfer the heat dissipated from the heat sink.

In some aspects, the techniques described herein relate to a wireless charging system, wherein the heat sink is a metal heat sink and is disposed between the charging unit and the thermoelectric module.

In some aspects, the techniques described herein relate to a wireless charging system, further including another heat sink dissipating heat generated from the charging unit, wherein the another heat sink is in contact with the fan and the thermoelectric module.

In some aspects, the techniques described herein relate to a wireless charging system, wherein the thermoelectric module is a Peltier cooling module.

In some aspects, the techniques described herein relate to a wireless charging system, wherein the first thermally conductive sheet is a metal sheet.

In some aspects, the techniques described herein relate to a wireless charging system, wherein the first thermal conductive sheet includes one or more of a copper pad, a thermal pad, a thermal paste.

In some aspects, the techniques described herein relate to a wireless charging system, wherein a gap exists between the heat sink and the charging unit to separate cool components from hot components.

In some aspects, the techniques described herein relate to a wireless charging system, further including a circuit board disposed between the first thermally conductive sheet and the second thermally conductive sheet and connected to the thermoelectric module.

In some aspects, the techniques described herein relate to a wireless charging system, further including a housing that includes the charging unit, the thermoelectric module, the first thermally conductive sheet, the heat sink, the fan, and the second thermally conductive sheet.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The accompanying drawings, which are incorporated into and constitute a part of this specification, illustrate one or more example aspects of the present disclosure and, together with the detailed description, serve to explain their principles and implementations.

FIG. 1 is an exploded view of a cooling wireless charging system, in accordance with exemplary aspects of the present disclosure.

FIG. 2 is a cross-sectional view of the cooling wireless charging system, in accordance with exemplary aspects of the present disclosure.

FIG. 3 is a cross-sectional view of a cooling wireless charging system with a single thermal spread sheet, in accordance with exemplary aspects of the present disclosure.

FIG. 4 is a diagram of a thermoelectric module, in accordance with exemplary aspects of the present disclosure.

FIG. 5 is a diagram of a first charging unit, in accordance with exemplary aspects of the present disclosure.

FIG. 6 is a diagram of a second charging unit, in accordance with exemplary aspects of the present disclosure.

FIG. 7 is an exploded view of a cooling wireless charging system with dual metal heat sinks, in accordance with exemplary aspects of the present disclosure.

FIG. 8 is a cross-sectional view of a cooling wireless charging system with dual metal heat sinks, in accordance with exemplary aspects of the present disclosure.

### DETAILED DESCRIPTION

Various aspects are now described with reference to the drawings. In the following description, for purposes of explanation, numerous specific details are set forth in order to provide a thorough understanding of one or more aspects. It may be evident, however, that such aspect(s) may be practiced without these specific details.

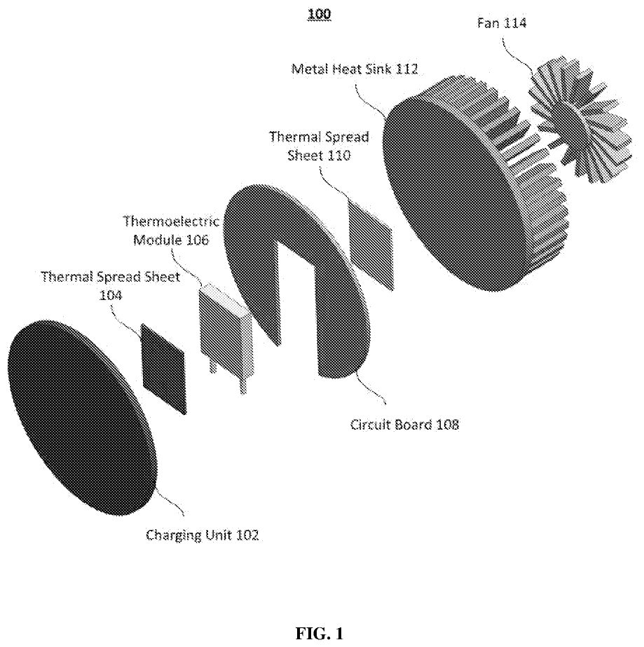

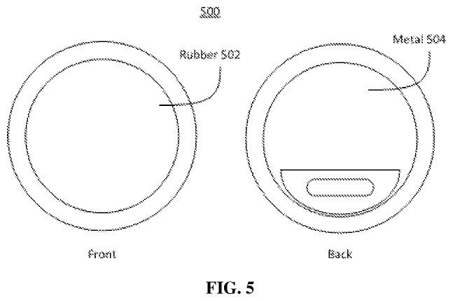

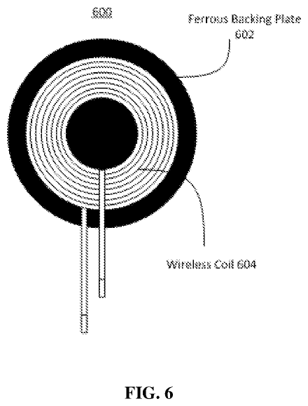

FIG. 1 is an exploded view of cooling wireless charging system 100, in accordance with exemplary aspects of the present disclosure. Wireless charging system 100 includes charging unit 102. As will be later discussed in FIGS. 5 and 6, charging unit 102 may be a MagSafe™ module or a Qi wireless charging module. Charging unit 102 generates an electromagnetic field such that when an electronic device (e.g., a wireless-charge-enabled smartphone) is placed near charging unit 102, a current is induced in its inductive coil, charging the battery of the electronic device.

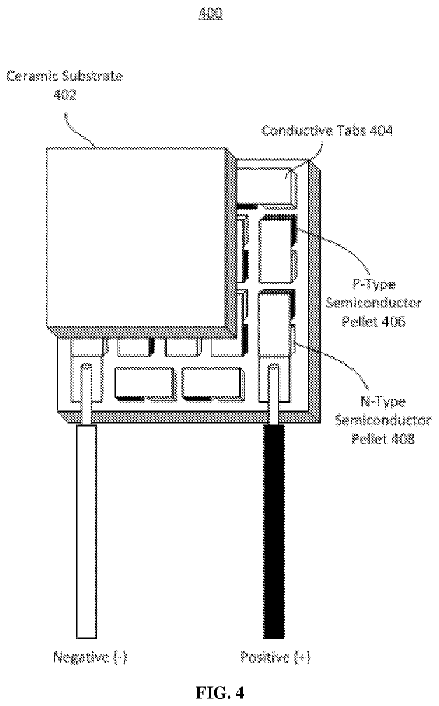

Wireless charging system 100 includes thermal spread sheet 104, which is a first thermally conductive sheet disposed between and in contact with charging unit 102 and thermoelectric module 106. Thermoelectric module 106 may be thermally coupled to charging unit 102 and configured to cool charging unit 102. As will be later discussed in FIG. 4, thermoelectric module 106 may be a Peltier cooling module.

Wireless charging system 100 includes circuit board 108, which is a printed circuit board assembly (PCBA). In some aspects, circuit board 108 may configured to control wireless charging system 100. Circuit board 108 is connected to thermoelectric module 106 and is disposed between thermal spread sheet 104 and thermal spread sheet 110. Thermal spread sheet 110 is a second thermally conductive sheet disposed between and in contact with metal heat sink 112 and thermoelectric module 106. Metal heat sink 112 dissipates heat from at least one side of thermoelectric module 106. In some aspects, thermal spread sheet 110 transfers heat from the surface of thermoelectric module 106 to metal heat sink 112. Thermal spread sheet 110 facilitates better contact between the surface of thermoelectric module 106 and metal heat sink 112. In some aspects, thermal spread sheet 104 and thermal spread sheet 110 are made of any combination of copper, a thermal pad, and a thermal paste. Metal heat sink 112 dissipates heat generated from charging unit 102. Lastly, wireless charging system 100 includes fan 114 that generates airflow in order to transfer the heat dissipated from metal heat sink 112.

When these components are placed in the manner described above, they can remove a large amount of heat from the wireless coil components. The benefit of wireless charging system 100 results in an improved efficiency of charging smartphones and other wireless devices up to 25% compared to standard Qi wireless charging without system 100 as shown in table 1 below:

TABLE 1
1 Hour Charging on iPhone ™ 12 with a silicon case

| Room | MagSafe with System 100 | | | MagSafe without System 100 | | |
|---|---|---|---|---|---|---|
| Temperature | Battery Level (Screen Off) | | | Battery Level (Screen Off) | | |
| (° C.) | Start % | End % | % Diff | Start % | End % | % Diff |
| 27 | 16 | 83 | 67 | 14 | 58 | 44 |

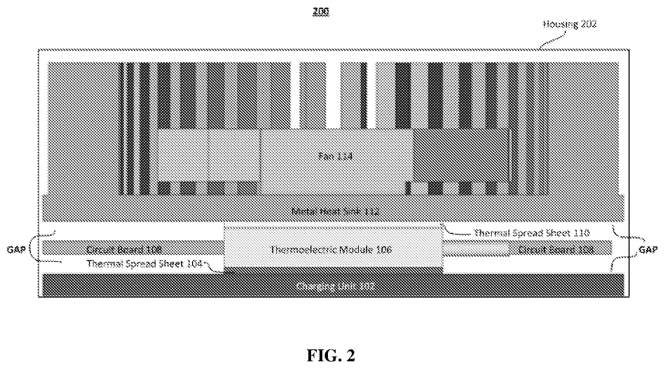

FIG. 2 is a cross-sectional view of cooling wireless charging system 200, in accordance with exemplary aspects of the present disclosure. Wireless charging system 200 is system 100 with housing 202. As can be seen, there is a gap between metal heat sink 112 and charging unit 102. More specifically, the gap exists between metal heat sink 112 and circuit board 108, as well as charging unit 102 and circuit board 108. This gap helps separate the hot components of system 200 with the cold components of system 200. A larger gap provides better separation than a smaller gap.

In some aspects, the sizes of each component are shown in table 2 below:

TABLE 2

| # | Component | Size(mm) |
|---|---|---|
| 1 | Fan 114 | D35 × 10 |
| 2 | Metal Heat Sink 112 | D52 × 13 |
| 3 | Thermoelectric Module 106 | 23 × 23 × 4 |
| 4 | Thermal Spread Sheets 104 and 110 | 23 × 23 × 0.5 |
| 5 | Charging Unit 102 | D44 × 1.8 |
| 6 | Circuit Board 108 | 76.2 × 51.5 × 1 |

In table 2, D represents diameter. In some aspects, the ratio of metal heat sink 112 and fan 114 is 10:7. It should be noted that if the size of metal heat sink 112 is increased, the size of fan 114 should be increased accordingly. In some aspects, the ratio of metal heat sink 112 and fan 114 can be adjusted based on the overall size of the wireless charging system 100.

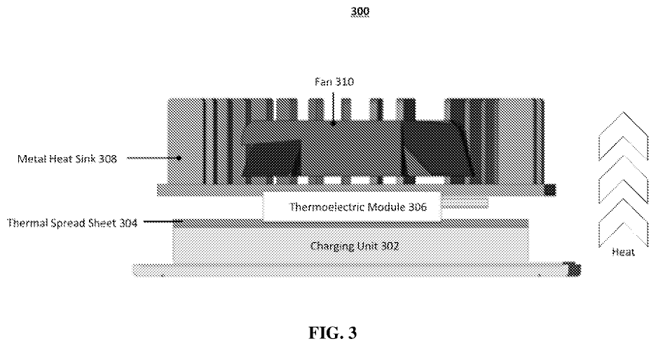

FIG. 3 is a cross-sectional view of cooling wireless charging system 300 with a single thermal spread sheet, in accordance with exemplary aspects of the present disclosure. System 300 is a simplified version of system 200, which does not include a second thermal spread sheet (i.e., thermal spread sheet 110) and a circuit board (i.e., circuit board 108). Accordingly, system 300 includes charging unit 302, thermal spread sheet 304, thermoelectric module 306, metal heat sink 308, and fan 310.

FIG. 4 is a diagram of thermoelectric module 400, in accordance with exemplary aspects of the present disclosure. As mentioned before, thermoelectric module 400 may be a Peltier system. A Peltier system is a module used to cool electronic components. In this case, thermoelectric module 400 is used in the specific stack of system 100 to cool charging unit 102. Thermoelectric module 400 includes P-type semiconductor pellets 406 and N-type semiconductor pellets 408. Thermoelectric module 400 further includes conductive tabs 404 and ceramic substrate 402. Thermoelectric module 400 works by reversing cold and hot surfaces; module 400 is improved when working with a fan (e.g., fan 114) and a heat sink (e.g., metal heat sink 112) to remove heat from hot elements.

FIG. 5 is a diagram of first charging unit 500, in accordance with exemplary aspects of the present disclosure. Charging unit 500 may use MagSafe™ technology, in which both the electronic device (RX) and wireless charger (TX) have a magnet array built-in to hold them together. MagSafe™ is included in the Made for iPhone (MFI) program, which allows 3rd party manufacturers to use their certified technology. System 100 is compatible with the MFI program. As shown in FIG. 5, charging unit 500 includes a front made of rubber 502 and a back plate made of metal 504.

FIG. 6 is a diagram of second charging unit 600, in accordance with exemplary aspects of the present disclosure. Charging unit 600 is a Qi wireless charging unit, which includes ferrous backing plate 602 and wireless coil 604. Either charging unit 500 or charging unit 600 may be used in the wireless charging systems described in the present disclosure.

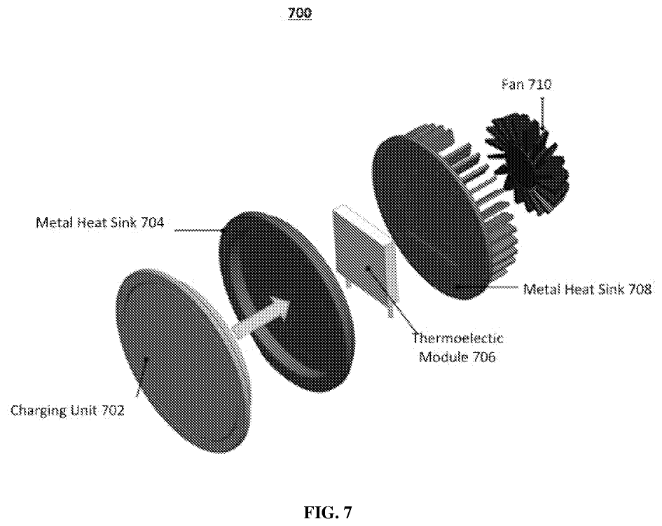

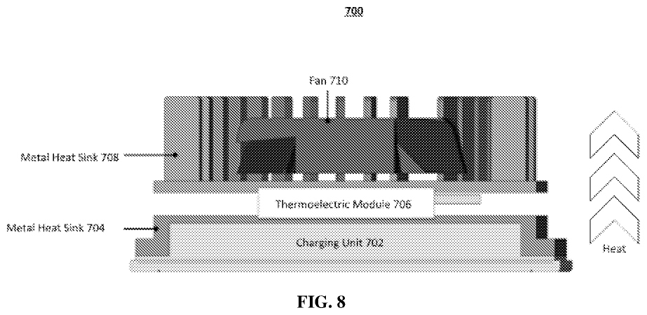

FIG. 7 is an exploded view of cooling wireless charging system 700 with dual metal heat sinks, in accordance with exemplary aspects of the present disclosure. FIG. 8 is a cross-sectional view of cooling wireless charging system 700 with dual metal heat sinks, in accordance with exemplary aspects of the present disclosure.

Wireless charging system 700 is made up of charging unit 702, metal heat sink 704, thermoelectric module 706, metal heat sink 708, and fan 710. Unlike the previously described versions of the wireless charging system, system 700 does not include any thermal spread sheets and instead includes metal heat sink 704 disposed between charging unit 702 and thermoelectric module 706. In some aspects, if additional heat sink (i.e., metal heat sink 108) contacts the surface of thermoelectric module 106, it may improve performance of wireless charging system 700.

While the foregoing disclosure discusses illustrative aspects and/or embodiments, it should be noted that various changes and modifications could be made herein without departing from the scope of the described aspects and/or embodiments as defined by the appended claims. Furthermore, although elements of the described aspects and/or embodiments may be described or claimed in the singular, the plural is contemplated unless limitation to the singular is explicitly stated. Additionally, all or a portion of any aspect and/or embodiment may be utilized with all or a portion of any other aspect and/or embodiment, unless stated otherwise.

What is claimed is:

1. A wireless charging system for charging a battery of an electronic device comprising:
a charging unit provided with an inductive coil, for generating an electromagnetic field such that when the electronic device is placed near the charging unit, a current is induced in the inductive coil charging the battery of the electronic device;
a thermoelectric module thermally coupled to the charging unit and configured to cool the charging unit;
a first thermally conductive sheet disposed between and in contact with the charging unit and the thermoelectric module;
a heat sink dissipating heat generated from the charging unit;
a fan generating airflow in order to transfer the heat dissipated from the heat sink; and
a second thermally conductive sheet disposed between and in contact with the heat sink and the thermoelectric module.

2. The wireless charging system of claim 1, further comprising at least one other fan generating airflow in order to transfer the heat dissipated from the heat sink.

3. The wireless charging system of claim 1, wherein the heat sink is a metal heat sink and is disposed between the charging unit and the thermoelectric module.

4. The wireless charging system of claim 1, further comprising another heat sink dissipating heat generated from the charging unit, wherein the another heat sink is in contact with the fan and the thermoelectric module.

5. The wireless charging system of claim 1, wherein the thermoelectric module is a Peltier cooling module.

6. The wireless charging system of claim 1, wherein the first thermally conductive sheet is a metal sheet.

7. The wireless charging system of claim 1, wherein the first thermal conductive sheet comprises one or more of a copper pad, a thermal pad, a thermal paste.

8. The wireless charging system of claim 1, wherein a gap exists between the heat sink and the charging unit to separate cool components from hot components.

9. The wireless charging system of claim 1, further comprising a circuit board disposed between the first thermally conductive sheet and the second thermally conductive sheet and connected to the thermoelectric module.

10. The wireless charging system of claim 1, further comprising a housing that includes the charging unit, the thermoelectric module, the first thermally conductive sheet, the heat sink, the fan, and the second thermally conductive sheet.

11. A method for wirelessly charging the electronic device using the wireless charging system of claim 1.
